(19) United States
(12) Patent Application Publication
(10) Pub. No.: US 2026/0181963 A1
(43) Pub. Date: Jun. 25, 2026

(54) MEMORY CELL

(71) Applicant: Floadia Corporation, Kodaira-shi (JP)

(72) Inventors: Shinji YOSHIDA, Kodaira-shi (JP); Yasuhiko KAWASHIMA, Kodaira-shi (JP); Satoshi NODA, Kodaira-shi (JP); Takashi YAMAKI, Kodaira-shi (JP); Shuichi SATO, Kodaira-shi (JP); Toshikazu MATSUI, Kodaira-shi (JP); Yasuhiro TANIGUCHI, Kodaira-shi (JP); Kosuke OKUYAMA, Kodaira-shi (JP)

(73) Assignee: Floadia Corporation, Kodaira-shi (JP)

(21) Appl. No.: 19/542,544

(22) Filed: Feb. 17, 2026

Related U.S. Application Data
(63) Continuation of application No. PCT/JP2025/027076, filed on Jul. 30, 2025.

(30) Foreign Application Priority Data
Jul. 31, 2024 (JP) 2024-125458
Jul. 30, 2025 (JP) 2025-127102

(51) Int. Cl. H10D 30/68; H10B 41/10; H10B 41/30; H10D 1/66; H10D 62/10

(52) U.S. Cl. CPC H10D 30/683; H10B 41/10; H10B 41/30; H10D 1/66; H10D 62/124

(57) ABSTRACT

A memory cell is capable of reliably injecting charges into a floating gate even when a film thickness of a gate insulating film is increased. The memory cell has a configuration in which a program transistor is constituted by a PMOS transistor, and electrons can be injected into a floating gate FG by hot electron injection using CHE. Accordingly, in the memory cell, even when film thicknesses of the gate insulating films are increased, the charges can be reliably injected into the floating gate FG.

### CROSS-REFERENCE RELATED APPLICATIONS

This is a continuation of International Application No. PCT/JP2025/027076 filed on Jul. 30, 2025, and claims the benefit of priority under 35 USC § 119 to Japanese Patent Applications 2024-125458 filed on Jul. 31, 2024, and No. 2025-127102 filed on Jul. 30, 2025, the entire contents of all of which are incorporated herein by reference.

### FIELD OF THE INVENTION

The present invention relates to a memory cell.

### BACKGROUND OF THE INVENTION

In the related art, a nonvolatile semiconductor memory device using a single layer polysilicon, which is used as a multi-time programmable memory or a one-time programmable memory, is known. JP2014-86435A discloses a nonvolatile semiconductor memory device in which one floating gate is shared by an erase capacitor, a read transistor, a program transistor, and a control capacitor, as a nonvolatile semiconductor memory device using a single layer polysilicon. In the nonvolatile semiconductor memory device disclosed in JP2014-86435A, charges are injected into the floating gate by a quantum tunneling effect.

### CITATION LIST

### Patent Literature

Patent Literature 1: JP2014-86435A

### Technical Problem

The nonvolatile semiconductor memory device using a single layer polysilicon can be used in various forms, and thus a film thickness of the gate insulating film may be increased. However, when the film thickness of the gate insulating film is increased, charges may be less likely to be injected into the floating gate by the quantum tunneling effect.

The present invention has been made in consideration of the above points, and an object thereof is to provide a memory cell capable of reliably injecting charges into a floating gate even when a film thickness of a gate insulating: film is increased.

### SUMMARY OF THE INVENTION

### Solution to Problem

A memory cell of the present invention is a memory cell of a nonvolatile semiconductor memory device, including: a program transistor; and a read transistor, in which the program transistor is formed in an N-type well, and includes a drain which is a P-type diffusion layer formed in a surface of the N-type well, a source which is a P-type diffusion layer formed in the surface of the N-type well and separated from the drain, a gate insulating film provided on the N-type well between the drain and the source, and a floating gate provided on the gate insulating film, the read transistor is formed in an N-type well, and includes a drain which is a P-type diffusion layer formed in a surface of the N-type well, a source which is a P-type diffusion layer formed in the surface of the N-type well and separated from the drain, a gate insulating film provided on the N-type well between the drain and the source, and a floating gate provided on the gate insulating film, and the floating gate of the program transistor and the floating gate of the read transistor are electrically connected to each other.

### Advantageous Effects of Invention

According to the present invention, the charges can be reliably injected into the floating gate even when the film thickness of the gate insulating film is increased.

### BRIEF DESCRIPTION OF THE DRAWINGS

FIG. 1 is a schematic diagram illustrating a side cross-sectional configuration of a memory cell according to a first embodiment.

FIG. 2 is a schematic diagram illustrating a planar layout example of the memory cell illustrated in FIG. 1.

FIG. 3A is a graph illustrating characteristics of a PMOS transistor having a standard gate length. FIG. 3B is a graph illustrating characteristics of a PMOS transistor having a gate length smaller than the standard gate length.

FIG. 4 is a schematic diagram illustrating a side cross-sectional configuration of a memory cell according to a second embodiment.

FIG. 5 is a schematic diagram illustrating a side cross-sectional configuration of a memory cell according to a third embodiment.

FIG. 6 is a schematic diagram illustrating a planar layout example of the memory cell illustrated in FIG. 5.

### DETAILED DESCRIPTION OF THE INVENTION

Hereinafter, preferred embodiments of the present invention will be described in detail with reference to the drawings. In the present specification and the drawings, components having substantially the same function are denoted by the same reference numerals, and repeated descriptions will be omitted.

### (1) First Embodiment

### (1-1) Configuration of Memory Cell According to First Embodiment

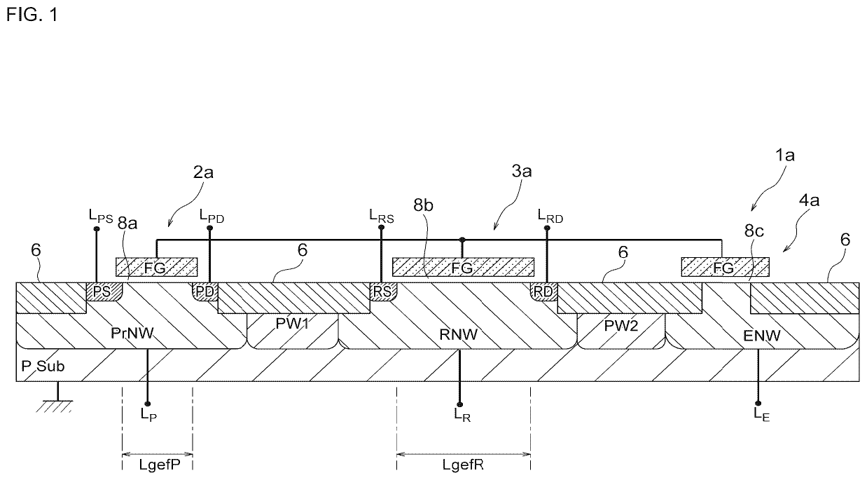

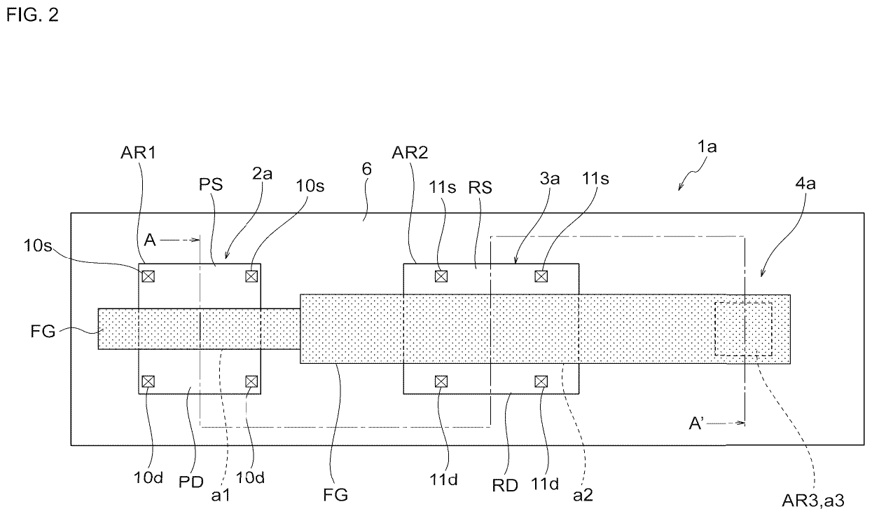

FIG. 1 is a schematic diagram illustrating a side cross-sectional configuration of a memory cell 1a according to a first embodiment. The memory cell 1a according to the first embodiment is used in a nonvolatile semiconductor memory device that is a multi-time programmable memory. FIG. 2 is a schematic diagram illustrating a planar layout example of the memory cell 1a illustrated in FIG. 1. FIG. 1 is a schematic diagram illustrating the side cross-sectional configuration of the memory cell 1a in a part A-A′ of FIG. 2.

In the memory cell 1a, a program transistor 2a, a read transistor 3a, and an erase capacitor 4a are provided on a P-type substrate PSub. The substrate PSub is, for example, a semiconductor substrate made of P-type single crystal silicon containing impurities such as boron.

The program transistor 2a is a P-channel metal oxide semiconductor (MOS) field effect transistor (FET) and is formed in an N-type well PrNW provided in the substrate PSub. A drain PD which is a P-type diffusion layer is formed in a surface of the N-type well PrNW, and a source PS which is a P-type diffusion layer is formed at a position spaced apart from the drain PD. A gate insulating film 8a made of silicon oxide or the like is provided on the N-type well PrNW between the drain PD and the source PS. The gate insulating film 8a is provided with a floating gate FG capable of storing charges. The floating gate FG is formed of P-type polysilicon containing impurities such as boron.

A film thickness of the gate insulating film 8a of the program transistor 2a (distance from the surface of the N-type well PrNW to a lower surface of the floating gate FG) is preferably 16 [nm] or more, more preferably 20 [nm] or more, and most preferably 30 [nm] or more. In the memory cell 1a according to the present embodiment, even when the film thickness of the gate insulating film 8a is increased, the charges can be injected into the floating gate FG by using a writing method using Channel Hot Electron (CHE) injection (channel hot electron injection) to be described later. A preferred range of the film thickness of the gate insulating film 8a of the program transistor 2a will be described in “(1-2) Principle of Data Write Operation” to be described later.

A source line L_{PS} is connected to the source PS of the program transistor 2a, and a predetermined voltage is applied to the source PS via the source line L_{PS}. The drain line L_{PD} is connected to the drain PD of the program transistor 2a. A well voltage line L_{P} is connected to the N-type well PrNW in which the program transistor 2a is formed, and a predetermined voltage is applied to the N-type well PrNW via the well voltage line L_{P}.

The read transistor 3a is a P-channel MOSFET and is formed in an N-type well RNW provided in the substrate PSub. A drain RD which is a P-type diffusion layer is formed in a surface of the N-type well RNW, and a source RS which is a P-type diffusion layer is formed at a position spaced apart from the drain RD. A gate insulating film 8b made of silicon oxide or the like is provided on the N-type well RNW between the drain RD and the source RS. The gate insulating film 8b is provided with the floating gate FG electrically connected to the floating gate FG of the program transistor 2a.

A source line L_{RS} is connected to the source RS of the read transistor 3a, and a predetermined voltage is applied to the source RS via the source line L_{RS}. In addition, a drain line LRD is connected to the drain RD of the read transistor 3a. A well voltage line LR is connected to the N-type well RNW in which the read transistor 3a is formed, and a predetermined voltage is applied to the N-type well RNW via the well voltage line LR.

A film thickness of the gate insulating film 8b of the read transistor 3a (distance from the surface of the N-type well RNW to the lower surface of the floating gate FG) is preferably the same as the film thicknesses of gate insulating films 8a and 8c of the program transistor 2a and the erase capacitor 4a. By setting the film thickness of the gate insulating film 8b of the read transistor 3a the same as the film thicknesses of the gate insulating films 8a and 8c of the program transistor 2a and the erase capacitor 4a, it is possible to collectively form the gate insulating films 8a, 8b, and 8c of the program transistor 2a, the read transistor 3a, and the erase capacitor 4a at the time of manufacturing the memory cell 1a.

The substrate PSub is formed with a P-type well PW1 between the N-type well PrNW in which the program transistor 2a is formed and the N-type well RNW in which the read transistor 3a is formed. The N-type well PrNW in which the program transistor 2a is formed and the N-type well RNW in which the read transistor 3a is formed are e electrically separated from each other by the P-type well PW1. In addition, an element isolation layer 6 is provided between an active region AR1 on the surface of the N-type well PrNW in which the program transistor 2a is formed and an active region AR2 on the surface of the N-type well RNW in which the read transistor 3a is formed. The active region AR1 of the program transistor 2a and the active region AR2 of the read transistor 3a are electrically separated from each other by the element isolation layer 6.

The erase capacitor 4a is a PMOS capacitor, and is formed in an N-type well ENW provided in the substrate PSub. The N-type well ENW is provided with a gate insulating film 8c made of silicon oxide or the like. The gate insulating film 8c is provided with the floating gate FG electrically connected to the floating gates FG of the program transistor 2a and the read transistor 3a.

A well voltage line LE is connected to the N-type well ENW in which the erase capacitor 4a is formed, and a predetermined voltage is applied to the N-type well ENW via the well voltage line LE.

A film thickness of the gate insulating film 8c of the erase capacitor 4a (distance from a surface of the N-type well ENW to the lower surface of the floating gate FG) is preferably 16 [nm] or more, more preferably 20 [nm] or more, and most preferably 30 [nm] or more. A preferred range of the gate insulating film 8c of the erase capacitor 4a will be described in “(1-5-1) Data Erase Operation Using SHH Injection” to be described later.

The substrate PSub is formed with a P-type well PW2 between the N-type well RNW in which the read transistor 3a is formed and the N-type well ENW in which the erase capacitor 4a is formed. The N-type well RNW in which the read transistor 3a is formed and the N-type well ENW in which the erase capacitor 4a is formed are electrically separated from each other by the P-type well PW2. In addition, the element isolation layer 6 is formed between the active region AR2 on the surface of the N-type well RNW in which the read transistor 3a is formed and the active region AR3 on the surface of the N-type well RNW of the erase capacitor 4a. The active region AR2 of the read transistor 3a and the active region AR3 of the erase capacitor 4a are electrically separated from each other by the element isolation layer 6.

As illustrated in FIG. 2, in the memory cell 1a, one floating gate FG is shared by the program transistor 2a, the read transistor 3a, and the erase capacitor 4a. In the memory cell 1a according to the present embodiment, the program transistor 2a, the read transistor 3a, and the erase capacitor 4a are linearly disposed, and the floating gate FG extends so as to intersect with the active region AR1 of the program transistor 2a, the active region AR2 of the read transistor 3a, and the active region AR3 of the erase capacitor 4a. The floating gate FG disposed in the active region AR1 of the program transistor 2a is formed in a rectangular shape in a plan view. In a short side direction of the floating gate FG in a plan view, the source PS which is a P-type diffusion layer, and the drain PD which is a P-type diffusion layer are disposed opposite each other with the floating gate FG interposed therebetween.

The source PS is provided with a columnar contact 10s connected to the source line L_{PS}. The drain PD is provided with a columnar contact 10d connected to the drain line L_{PD}. In the program transistor 2a according to the present embodiment, a length of the floating gate FG in the short side direction is a “gate length”, and a length of a region sandwiched between the source PS and the drain PD in the short side direction of the floating gate FG is an “effective gate length LgefP”.

The floating gate FG disposed in the active region AR2 of the read transistor 3a is formed in a rectangular shape in a plan view, and is formed continuously from the floating gate FG of the program transistor 2a. In the short side direction of the floating gate FG of the read transistor 3a in a plan view, the source RS which is a P-type diffusion layer, and the drain RD which is a P-type diffusion layer are disposed opposite each other with the floating gate FG interposed therebetween. The source RS is provided with a columnar contact 11s connected to the source line L_{RS}. The drain RD is provided with a columnar contact 11d connected to the drain line LRD.

In the read transistor 3a according to the present embodiment, a length of the floating gate FG in the short side direction is a “gate length”, and a length of a region sandwiched between the source RS and the drain RD in the short side direction of the floating gate FG is an “effective gate length LgefR”. Here, the effective gate length LgefP of the floating gate FG of the program transistor 2a is selected to be smaller than the effective gate length LgefR of the floating gate FG of the read transistor 3a.

The floating gate FG disposed in the active region AR3 of the erase capacitor 4a is formed in a rectangular shape in a plan view, and is formed continuously from the floating gates FG of the program transistor 2a and the read transistor 3a. In the present embodiment, the floating gate FG disposed in the active region AR2 of the read transistor 3a extends linearly to a region in which the erase capacitor 4a is formed while maintaining the length of the floating gate FG in the short side direction.

The floating gate FG covers the active region AR3 of the erase capacitor 4a, and the floating gate FG does not intersect with the active region AR3. In a configuration in which the floating gate FG intersects with the active region AR3, a voltage at which an avalanche phenomenon occurs varies due to a variation in a shape of an edge of the floating gate FG on the active region AR3 during the data erase operation using the SHH injection to be described later. With the configuration in which the floating gate FG covers the active region AR3 of the erase capacitor 4a, the variation in the voltage at which the avalanche phenomenon occurs can be reduced, and the data erase operation using the SHH injection can be reliably performed.

Here, in FIG. 2, in a plan view, an area at which the floating gate FG disposed in the program transistor 2a and the active region AR1 of the program transistor 2a face each other is illustrated as a1. In addition, an area at which the floating gate FG disposed in the read transistor 3a and the active region AR2 of the read transistor 3a face each other is illustrated as a2, and an area at which the floating gate FG disposed in the erase capacitor 4a and the active region AR3 of the erase capacitor 4a face each other is illustrated as a3.

In the present embodiment, the area a3 at which the floating gate FG and the active region AR3 of the erase capacitor 4a face each other is preferably 10[%] or less of a total area (area a1+area a2+area a3) of the area a1 at which the floating gate FG and the active region AR1 of the program transistor 2a face each other, the area a2 at which the floating gate FG and the active region AR2 of the read transistor 3a face each other, and the area a3 at which the floating gate FG and the active region AR3 of the erase capacitor 4a face each other, and more preferably 5[%] or less of the total area. By setting the area a3 to 10[%] or less of the total area (area a1+area a2+area a3), a coupling ratio of the erase capacitor 4a can be reduced, and a potential of the floating gate FG can be prevented from being affected during a data write operation or a data erase operation. By setting the area a3 to 5[%] or less of the total area (area a1+area a2+area a3), the coupling ratio of the erase capacitor 4a can be reduced, and the potential of the floating gate FG can be further prevented from being affected during the data write operation or the data erase operation. Details will be described in “(1-4) Data Write Operation”.

In the present embodiment, the area a2 of the active region AR2 facing the floating gate FG of the read transistor 3a is preferably larger than the area a1 of the active region AR1 facing the floating gate FG of the program transistor 2a. Accordingly, when a high positive well voltage Vrw is applied to the N-type well RNW of the read transistor 3a, an effect of effectively increasing the potential of the floating gate FG by capacitive coupling can be enhanced.

The memory cell 1a can be manufactured by performing a film forming process that is a general manufacturing process of a PMOS transistor, a photolithography process, an etching process, an impurity injection process, and the like, and thus the manufacturing method thereof will be omitted here.

### (1-2) Principle of Data Write Operation

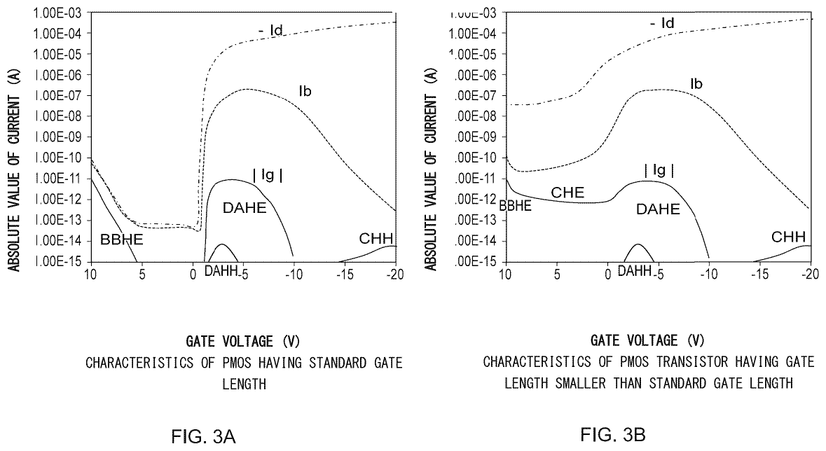

Next, the principle of the data write operation in the memory cell 1a will be described. Here, FIG. 3A is a graph illustrating characteristics of the PMOS transistor having a standard gate length, and FIG. 3B is a graph illustrating characteristics of the PMOS transistor having a gate length smaller than the standard gate length. The gate length of the PMOS transistor having a standard gate length in FIG. 3A is equal to a gate length of a PMOS transistor of a standard logic circuit of the nonvolatile semiconductor memory device in which the PMOS transistor is used. The gate length is a minimum processing dimension of a process generation in which the nonvolatile semiconductor memory device is manufactured.

FIG. 3A and FIG. 3B are graphs illustrating a drain current (“−Id”), a substrate current (“Ib”), and a gate current (“|Ig|”) with respect to a gate voltage when the gate voltage is changed from +10 [V] to −20 [V] by respectively setting a well voltage and a source voltage of the PMOS transistor to 0 [V], and applying a negative high voltage of −10 [V] to the drain. A horizontal axis represents the gate voltage [V], and a vertical axis represents a current value (absolute value of current) [A] of each current represented by logarithm.

In the PMOS transistor having a standard gate length in FIG. 3A, when the gate voltage exceeds a threshold voltage, the drain current rapidly increases. On the other hand, the PMOS transistor having a gate length smaller than the standard gate length in FIG. 3B is in a punch-through state, the drain current also flows when the gate voltage is lower than the threshold voltage (hereinafter, a direction in which an absolute value is large on a negative voltage side of the gate voltage is referred to as “high”, and a direction in which the absolute value is large on a positive voltage side of the gate voltage is referred to as “low”).

FIGS. 3A and 3B illustrate a gate current by carrier injection using Drain Avalanche Hot Electron (DAHE), Drain Avalanche Hot Hole (DAHH), Band to Band Tunneling Induced Hot Electron (BBHE), Channel Hot Hole (CHH), and Channel Hot Electron (CHE), which are types of hot carrier injection modes.

In the DAHE injection, electrons obtaining energy in a large horizontal electric field in the vicinity of the drain in a state in which a channel is pinched off are injected into a gate oxide film beyond an energy barrier of a Si—SiO₂ interface. In the DAHH injection, holes obtaining energy in the large horizontal electric field in the vicinity of the drain in the state in which the channel is pinched off are injected into the gate oxide film beyond the energy barrier of the Si—SiO₂ interface. The DAHE injection and the DAHH injection cause the gate current to reach a peak before the drain current starts to flow and the substrate current reaches a peak. In particular, a significant current is observed in the PMOS transistor, and a positive voltage is applied to the gate more than to the drain, and thus electrons are likely to be injected, and the DAHE becomes dominant. In the DAHH injection, a range of the generated gate voltage is narrow, and a ratio of injection is also small, as compared with the DAHE injection, but the DAHH injection also occurs in the PMOS transistor because the hole injection also occurs. The gate current by the BBHE injection occurs when the gate voltage is a large positive value and a voltage between drain and substrate voltage is high. In the CHH injection, the holes obtaining energy from an electric field in a channel horizontal direction are injected into the gate oxide film beyond the energy barrier of the Si—SiO₂ interface by an electric field in a channel vertical direction. Accordingly, a gate current may occur at a voltage with the gate voltage is at a large negative voltage.

Next, the CHE injection will be described. In the PMOS transistor having a standard gate length in FIG. 3A, the drain current is cut off at a gate voltage of 0 [V], and thus no gate current by the CHE injection is observed. However, when the gate length is small and the drain voltage is high, the PMOS transistor is in a punch-through state, the drain current cannot be cut off even when the gate voltage is lowered, and carriers that have become hot by obtaining the energy from the electric field in the channel horizontal direction are injected into the gate oxide film beyond the energy barrier of the Si—SiO₂ interface by the electric field in the channel vertical direction. In FIG. 3B, the gate current by the CHE injection is observed in a range of the gate voltage of +9 [V] to 0 [V]. Such a phenomenon has not been discussed in the related art. The inventors of the present application focused on the CHE phenomenon that is remarkably observed in the PMOS transistor in the punch-through state, which has not been discussed in the related art, and used the CHE phenomenon for writing data.

In the memory cell 1a according to the present embodiment, data is written by injecting charges into the floating gate FG of the program transistor 2a using the CHE injection in the PMOS transistor in the punch-through state. In order to implement the PMOS transistor in the punch-through state, the effective gate length LgefP of the floating gate FG of the program transistor 2a is reduced in the memory cell 1a according to the present embodiment. The effective gate length LgefP of the floating gate FG of the program transistor 2a is preferably smaller than the effective gate length of the transistor of the standard logic circuit of the nonvolatile semiconductor memory device in which the memory cell 1a is used. In addition, the effective gate length LgefP of the floating gate FG of the program transistor 2a is preferably smaller than the minimum processing dimension of the process generation in which the nonvolatile semiconductor memory device is manufactured.

As a specific method of reducing the effective gate length LgefP of the program transistor 2a, for example, there is a method of reducing the gate length of the program transistor 2a in the photolithography process and/or the etching process. Alternatively, there is a method of implanting the source PS and the drain PD of the program transistor 2a inside the edge of the floating gate FG by tilt ion injection, thereby reducing a distance between the source PS and the drain PD. In addition, there is a method of providing a constriction or a notch in a part of the floating gate FG on the active region AR1 of the program transistor 2a.

Here, a case has been described in which the effective gate length LgefP of the program transistor 2a is reduced to create the punch-through state, and the charges are injected into the floating gate FG of the program transistor 2a using the CHE injection, but the present invention is not limited thereto. For example, instead of reducing the effective gate length LgefP of the program transistor 2a, an impurity concentration of the channel of the program transistor 2a may be adjusted, thereby lowering the threshold voltage, and thus the punch-through is more likely to occur than in the transistor of the standard logic circuit. Even by such a method, the charges can be injected into the floating gate FG of the program transistor 2a using the CHE injection.

In the PMOS transistor in the punch-through state, a subthreshold swing, which is an amount of change in the gate voltage required to increase the drain current by one digit, deteriorates and becomes a large numerical value. A subthreshold swing of the program transistor 2a of the memory cell 1a according to the present embodiment, when the drain voltage is −10 [V], is preferably larger than 400 [mV/dec].

In the PMOS transistor in the punch-through state, the drain current increases with increasing the drain voltage even in a saturation region due to a drain-induced barrier reduction (DIBL) and a channel length modulation effect. A channel length modulation ratio of the program transistor 2a of the memory cell 1a according to the present embodiment, which is a ratio of the drain current in the saturation region when the drain voltage is −10 [V] with respect to the drain current in the saturation region when the drain voltage is −2 [V], is preferably twice or more.

The PMOS transistor in the punch-through state has a small on/off ratio. An on/off ratio of the program transistor 2a of the memory cell 1a according to the present embodiment, which is a ratio of an ON current when the drain voltage is −10 [V] and the gate voltage is −10 [V] to an OFF current when the drain voltage is −10 [V] and the gate voltage is 0 [V], is preferably 5 digits or less.

In the memory cell 1a according to the present embodiment, the subthreshold swing of the program transistor 2a is larger than a subthreshold swing of the read transistor 3a. In the memory cell 1a according to the present embodiment, the channel length modulation ratio of the program transistor 2a is larger than a channel length modulation ratio of the read transistor 3a. In the memory cell 1a according to the present embodiment, the on/off ratio of the program transistor 2a is smaller than an on/off ratio of the read transistor 3a.

(1-3) Configuration in which Read Transistor is Provided Separately from Program Transistor

When the CHE injection is used for the data write operation, it is preferred to reduce the effective gate length LgefP of the program transistor 2a so that punch-through occurs in the program transistor 2a. In addition, if the CHE occurs, there is a risk that the transistor characteristics may be deteriorated. For example, when the data read operation is also performed by the program transistor 2a without providing the read transistor 3a, this may cause problems such as a shift in a threshold voltage Vth on read information, and narrowing a read allowable limit.

Therefore, in the present embodiment, in order to avoid occurrence of a failure when a read operation is performed using the program transistor 2a, the program transistor 2a for writing data and the read transistor 3a for reading data are separately provided, and the program transistor 2a is not used for reading data but is used exclusively for writing data. In addition, in order to generate the CHE in the program transistor 2a, the effective gate length LgefP is made small to cause a punch-through state, while in order to prevent the read transistor 3a from becoming a punch-through state, it is preferred to make the effective gate length LgefR larger than the effective gate length LgefP of the program transistor 2a.

The effective gate length LgefR of the floating gate FG of the read transistor 3a is preferably the same as the effective gate length of the transistor of the standard logic circuit of the nonvolatile semiconductor memory device in which the memory cell 1a is used. In addition, the effective gate length LgefR of the floating gate FG of the read transistor 3a is preferably the minimum processing dimension of the process generation in which the nonvolatile semiconductor memory device is manufactured.

Therefore, in the memory cell 1a according to the present embodiment, the effective gate length LgefP of the floating gate FG of the program transistor 2a is selected to be smaller than the effective gate length LgefR of the floating gate FG of the read transistor 3a.

### (1-4) Data Write Operation

Next, a data write operation using the CHE injection in the memory cell 1a will be described. The following Table 1 shows a specific example (voltage example) of a combination of voltages during the data write operation in a column of “Write”. A unit of the voltage value shown in Table 1 is “V”.

TABLE 1

| | Operations | PS | PD | RS | RD | PrNW | RNW | ENW | Psub |
|---|---|---|---|---|---|---|---|---|---|
| First | Write | 12 | 0 | open | open | 12 | 16 | open | 0 |
| Embodiment | Erase | open | open | open | open | 0 | 0 | 40 | 0 |
| | Read | open | open | 5 | 0 | 5 | 5 | open | 0 |

When the data is written by the program transistor 2a, for example, the substrate PSub is set to 0 [V]. In the program transistor 2a, for example, a source voltage V_{PS} of +12 [V] is applied to the source PS, the drain PD is set to 0 [V], and a well voltage Vprw of +12 [V] is applied to the N-type well PrNW.

Accordingly, in the program transistor 2a, hot electrons are injected into the floating gate FG beyond an energy barrier of an interface between the N-type well PrNW and the gate insulating film 8a and an energy barrier of the gate insulating film 8a by the CHE injection. The program transistor 2a is in a state in which the hot electrons injected into the floating gate FG are stored and resulting in a state where the data is written. Although the source voltage V_{PS} and the well voltage Vprw are set to +12 [V] as an example, the source voltage V_{PS} and the well voltage Vprw can also be set to a higher voltage within a range that does not exceed a junction breakdown voltage of the source PS and the N-type well PrNW, and the data write speed can be increased by setting the source voltage V_{PS} and the well voltage Vprw to high voltages. For example, when the junction breakdown voltage between the source PS and the N-type well PrNW is 17 [V], the source voltage V_{PS} and the well voltage Vprw can be set to about 16.5 [V] at maximum.

During the data write operation, in the read transistor 3a, for example, the source RS and the drain RD are opened, and the well voltage Vrw of +16 [V] is applied to the N-type well RNW. The well voltage Vrw applied to the N-type well RNW of the read transistor 3a is preferably equal to or higher than the well voltage Vprw applied to the N-type well PrNW of the program transistor 2a (positive voltage whose absolute value is equal to or higher than the well voltage Vprw).

For example, when the well voltage Vprw of +12 [V] is applied, if the well voltage Vrw of +16 [V] is applied, the potential of the floating gate FG during the data write operation can be shifted to a positive side as compared with that when no well voltage Vrw is applied, and thus an injection efficiency of the hot electrons of the CHE injection can be enhanced. In other words, in the PMOS transistor, when the direction in which the absolute value is large on the negative voltage side of the gate voltage is referred to as “high” and the direction in which the absolute value is large on the positive voltage side of the gate voltage is referred to as “low”, the voltage of the floating gate FG can be lowered in effect by the capacitive coupling, and thus the injection efficiency of the hot electrons of the CHE injection can be enhanced. Accordingly, for example, a data write time can be shortened. In the present embodiment, the N-type well RNW of the read transistor 3a is physically and electrically separated from the N-type well PrNW of the program transistor 2a. Therefore, the well voltage Vrw having a voltage value different from that of the N-type well PrNW of the program transistor 2a can be applied to the N-type well RNW of the read transistor 3a.

The read transistor 3a is selected such that the area a2 of the active region AR2 facing the floating gate FG is larger than the area a1 of the active region AR1 facing the floating gate FG of the program transistor 2a or the area a3 of the active region AR3 facing the floating gate FG of the erase capacitor 4a. Accordingly, when a high positive well voltage Vrw is applied to the N-type well RNW of the read transistor 3a, the effect of effectively lowering the potential of the floating gate FG by the capacitive coupling can be enhanced.

During the data write operation, for example, the N-type well ENW is opened in the erase capacitor 4a. Here, the larger the area of the active region facing the floating gate FG is, the larger the effect that the well voltage has on the potential of the floating gate FG by the capacitive coupling. In the erase capacitor 4a, the area a3 at which the floating gate FG and the active region AR3 face each other is 10[%] or less of the total area (area a1+area a2+area a3), and thus the influence of the well voltage Vew of the N-type well ENW on the potential of the floating gate FG can be reduced by the capacitive coupling.

The memory cell 1a according to the present embodiment writes data by using the CHE injection in the PMOS transistor in the punch-through state and setting the potential of the floating gate FG to a positive voltage. As illustrated in FIG. 3B, a drain current Id when the potential of the floating gate FG is on the positive voltage side is smaller than a drain current Id when the potential of the floating gate FG is on the negative voltage side. Therefore, the power consumption during writing can be reduced.

### (1-5) Data Erase Operation

### (1-5-1) Data Erase Operation Using SHH Injection

Next, a data erase operation in the memory cell 1a will be described. In the memory cell 1a according to the present embodiment, the data is erased by injecting hot holes into the floating gate FG by Substrate Hot Hole (SHH) injection.

When the gate voltage is fixed to 0 [V] and a high positive voltage is applied to the well in the PMOS capacitor, the current flowing from the well to the gate rapidly increases when the positive voltage applied to the well exceeds, for example, about 40 [V]. This is caused by the SHH injection. It is considered that, in the SHH injection, the electric field applied to a band of the N-type well becomes strong in the PMOS capacitor, the holes are more accelerated, the accelerated holes collide with a grid, a new carrier is generated, and the generation of the carrier is performed in a preferred circulation, resulting in an avalanche. This avalanche phenomenon does not occur in a Fowler-Nordheim (FN) tunneling. By using the SHH injection, the holes can be injected into the floating gate FG faster than by using the FN tunneling is used. Further, By using the SHH injection, the area a3 at which the floating gate FG and the active region AR3 of the erase capacitor 4a face each other can be reduced.

The following Table 1 shows a specific example (voltage example) of a combination of voltages during the data erase operation using the SHH injection in a column of “Erase”. When the data is erased by the erase capacitor 4a, the substrate PSub is set to 0 [V]. In the erase capacitor 4a, for example, the well voltage Vew of 40 [V] or more is applied to the N-type well ENW. A voltage range of the well voltage Vew applied to the N-type well ENW is preferably higher than the voltage causing the avalanche phenomenon from the viewpoint of erasing the data at a high speed. Here, the voltage causing the avalanche phenomenon is set to 40 [V] or higher, but the voltage causing the avalanche phenomenon depends on a concentration or a depth of the well, and thus the voltage varies depending on manufacturing conditions of the semiconductor. In the program transistor 2a, the source PS and the drain PD are opened, and the N-type well PrNW is set to 0 [V]. In addition, in the read transistor 3a, the source RS and the drain RD are opened, and the N-type well RNW is set to 0 [V].

As described above, the larger the area of the active region facing the floating gate FG is, the larger the effect that the well voltage has on the potential of the floating gate FG by the capacitive coupling. In the memory cell 1a according to the present embodiment, the area a3 at which the floating gate FG and the active region AR3 of the erase capacitor 4a face each other is smaller than the total area (area a1+area a2+area a3) of the area a1 at which the floating gate FG and the active region AR1 of the program transistor 2a face each other, the area a2 at which the floating gate FG and the active region AR2 of the read transistor 3a face each other, and the area a3 of the active region AR3 facing the floating gate FG of the erase capacitor 4a, and a coupling ratio represented by the area a3/(area a1+area a2+area a3) is small (for example, 5% or less). Therefore, in the present embodiment, even when a high voltage well voltage Vew is applied to the active region AR3 of the erase capacitor 4a having a small area a3 at which the active region AR3 and the floating gate FG face each other, the high voltage is less likely to affect the floating gate FG. Therefore, in the erase capacitor 4a, most of the high well voltage Vew (for example, 95% or more) can be used for bending the band of the N-type well ENW and injecting the holes.

In the memory cell 1a, the coupling ratio of the program transistor 2a (area a1/(area a1+area a2+area a3)) and the coupling ratio of the read transistor 3a (area a2/(area a1+ area a2+area a3)) are large, and thus by respectively setting the well voltage Vprw and the well voltage Vrw to 0 [V] during the erase operation, the potential of the floating gate FG can be adjusted so as not to float with respect to 0 [V].

When the SHH injection is used as a data erase method, high-energy hot holes are injected into the floating gate beyond the energy barrier of the gate insulating film, but this energy may cause defects in the gate insulating film, and the holes may be trapped in these defects.

Here, as described in Publicly Known Document 1 (Tunnel oxide and ETOX flash scaling limitation) and Publicly Known Document 2 (Limitations on Oxide Thicknesses in FLASH EEPROM Application), normally, if the film thickness of the gate insulating film is about 8 [nm], the probability that the electrons in the floating gate tunnel through the gate insulating film becomes sufficiently small, and there is no problem in data retention.

When the holes are trapped in the defects in the gate insulating film, the probability that the electrons tunnel through the gate insulating film is highest when a position of the trap is near the center in the thickness direction of the gate insulating film. A minimum film thickness of the gate insulating film capable of ensuring the reliability is about 8 [mm] as described above, and thus in order to ensure the reliability even when the holes are trapped, a film thickness from the trap position to the substrate may be about 8 [nm], and a film thickness from the trap position to the floating gate may be about 8 [nm]. As described above, when the data erase method using the SHH is used, the film thickness of the gate insulating film 8c is preferably 16 [nm] or more.

When the data is written by the hot carrier injection, hot hole injection caused by DAHH occurs in a region in which the gate voltage is close to 0 [V], and thus even when writing is performed by injecting the hot electrons into the floating gate using the CHE injection, the hot hole injection using the DAHH may not be prevented depending on the potential of the floating gate. The hot holes using the DAHH may also be trapped in the defects in the gate insulating film.

As described above, in the program transistor 2a in which the data is written by injecting the hot electrons into the floating gate FG, the film thickness of the gate insulating film 8a is also preferably 16 [nm] or more.

### (1-5-2) Data Erase Operation Using FN Tunneling

In the above embodiment, a case in which the data is erased by injecting the hot holes from the N-type well ENW into the floating gate FG of the erase capacitor 4a by the SHH injection has been described, but the present invention is not limited thereto. For example, the data may be erased by injecting the holes from the N-type well ENW into the floating gate FG of the erase capacitor 4a by the FN tunneling.

In the FN tunneling, when the electric field applied to the gate insulating film does not exceed a certain value (for example, 12 [MV/cm]), no tunnel current flows, and thus as the film thickness of the gate insulating film increases, it is necessary to increase the applied voltage. On the other hand, in the case of SHH, the generation of the hot holes is determined by the concentration of the well and the bending of the band of the well, and thus is less likely to be affected by the film thickness of the gate insulating film. Therefore, when the data is erased by the SHH injection, the positive voltage applied to the N-type well ENW may not be increased even when the film thickness of the gate insulating film 8c is increased.

### (1-6) Data Read Operation

Next, a data read operation in the memory cell 1a will be described. The above Table 1 shows a specific example (voltage example) of a combination of voltages during the data read operation in a column of “Read”. When the data is read, in the read transistor 3a, for example, the drain RD is set to 0 [V], the source voltage VRs of 5 [V] is applied to the source RS, and the well voltage Vrw of 5 [V] is applied to the N-type well RNW. In the program transistor 2a, the source PS and the drain PD are opened, and for example, the well voltage Vprw of 5 [V] is applied to the N-type well PrNW. The N-type well ENW is opened in the erase capacitor 4a.

Here, for example, in the memory cell 1a in which electrons are stored in the floating gate FG (data is written), the threshold voltage of the read transistor 3a (hereinafter, also referred to as Vth) is low (direction in which the absolute value is large on the negative voltage side of the gate voltage is referred to as “high”, and direction in which the absolute value is large on the positive voltage side of the gate voltage is referred to as “low”), when the data is read, the read transistor 3a is turned on, and a current flowing between the source RS and the drain RD of the read transistor 3a increases. On the other hand, in the memory cell 1a in which no electrons are stored in the floating gate FG (no data is written), the Vth of the read transistor 3a is high (direction in which the absolute value is large on the negative voltage side of the gate voltage is referred to as “high”, and direction in which the absolute value is large on the positive voltage side of the gate voltage is referred to as “low”), when the data is read, the read transistor 3a is turned off, and the current flowing between the source RS and the drain RD decreases. Accordingly, in the memory cell 1a, for example, the data can be read by detecting the current flowing between the source RS and the drain RD of the read transistor 3a.

### (1-7) Operations and Effects

The memory cell 1a according to the present embodiment includes the program transistor 2a formed in the N-type well PrNW and the read transistor 3a formed in the N-type well RNW. The program transistor 2a is a PMOS transistor including the drain PD which is a P-type diffusion layer formed in the surface of the N-type well PrNW, the source PS which is a P-type diffusion layer formed in the surface of the N-type well PrNW and separated from the drain PD, the gate insulating film 8a which is provided on the N-type well PrNW between the drain PD and the source PS, and the floating gate FG which is provided on the gate insulating film 8a.

The read transistor 3a is a PMOS transistor including the drain RD which is a P-type diffusion layer formed in the surface of the N-type well RNW, the source RS which is a P-type diffusion layer formed in the surface of the N-type well RNW and separated from the drain RD, the gate insulating film 8b which is provided on the N-type well RNW between the drain RD and the source RS, and the floating gate FG which is provided on the gate insulating film 8b. The floating gate FG of the program transistor 2a and the floating gate FG of the read transistor 3a are electrically connected to each other.

The memory cell 1a according to the present embodiment has a configuration in which the program transistor 2a is constituted by a PMOS transistor, and the electrons can be injected into the floating gate FG by the hot electron injection using the CHE, and thus even when the film thickness of the gate insulating film 8a is increased, the charges can be reliably injected into the floating gate FG.

In the memory cell 1a, the electrons are injected into the floating gate FG by the CHE injection, and thus the data write time can be shortened as compared with the write operation using the FN tunneling. In addition, in the memory cell 1a, the program transistor 2a is constituted by the PMOS transistor, and thus a voltage for the hot carrier injection can be made lower than that in a case in which the program transistor 2a is constituted by an NMOS transistor, and the data write operation is performed at a low voltage.

The memory cell 1a according to the present embodiment is provided with the erase capacitor 4a, and the data can be repeatedly written and erased by the program transistor 2a and the erase capacitor 4a, and thus the memory cell 1a can be used as a memory cell of a multi-time programmable memory.

In the memory cell 1a, the read transistor 3a is provided separately from the program transistor 2a, and thus even when the data write and erase operations are repeated and the characteristic degradation occurs due to the CHE injection repeated in the program transistor 2a, the characteristic degradation does not occur in the read transistor 3a, and the Vth can be read with high accuracy.

In the memory cell 1a, the N-type well PrNW in which the program transistor 2a is formed and the N-type well RNW in which the read transistor 3a is formed are electrically separated from each other, whereby the data write time can be shortened.

The erase capacitor 4a is formed in the N-type well ENW electrically separated from the N-type well PrNW in which the program transistor 2a is formed and the N-type well RNW in which the read transistor 3a is formed. In addition, the erase capacitor 4a is a PMOS capacitor including the gate insulating film 8c provided on the N-type well ENW and the floating gate

FG provided on the gate insulating film 8c. The floating gate FG of the erase capacitor 4a is electrically connected to the floating gate FG of the program transistor 2a and the floating gate FG of the read transistor 3a.

The memory cell 1a according to the present embodiment has a configuration in which the erase capacitor 4a is constituted by the PMOS capacitor and the holes can be injected into the floating gate FG by the hot hole injection using the SHH, and thus the holes can be injected into the floating gate FG faster than when the FN tunneling is used, and an erase time can be shortened. In addition, when the data is erased using the SHH, even when the film thickness of the gate insulating film 8c of the erase capacitor 4a is increased, the holes can be injected without increasing the well voltage Vew. Further, by erasing the data using the SHH injection, the area a3 at which the floating gate FG and the active region AR3 of the erase capacitor 4a face each other can be reduced, and the coupling ratio of the erase capacitor 4a can be reduced. By reducing the coupling ratio of the erase capacitor 4a, the effect of the well voltage Vew on the potential of the floating gate FG can be reduced, and thus a high well voltage Vew can be applied to the N-type well ENW, and the holes can be efficiently injected into the floating gate FG.

### (1-8) Other Embodiments of First Embodiment

In the first embodiment, the memory cell 1a is described as being used in the nonvolatile semiconductor memory device that is a multi-time programmable memory, but the present invention is not limited thereto and may also be, for example, a memory cell used in the nonvolatile semiconductor memory device that is a one-time programmable memory. In the memory cell of the one-time programmable memory, the erase capacitor 4a is not required, and thus the memory cell includes the program transistor 2a and the read transistor 3a.

In the memory cell 1a that does not include the erase capacitor 4a, the data write operation and the data read operation can also be performed in the same manner as the above “(1-4) Data Write Operation” and “(1-6) Data Read Operation”. In addition, a specific example (voltage example) of the combination of voltages in the data write operation and the data read operation at this time has the same voltage value as the voltage value shown in Table 1.

### (2) Second Embodiment

### (2-1) Configuration of Memory Cell According to Second Embodiment

In the first embodiment, the memory cell 1a in which the N-type well PrNW in which the program transistor 2a is formed and the N-type well RNW in which the read transistor 3a is formed are electrically separated from each other has been described, the present invention is not limited thereto, and the memory cell may be a memory cell provided with one N-type well in which the N-type well in which the program transistor is formed and the N-type well in which the read transistor is formed are electrically connected to each other.

A memory cell according to a second embodiment is characterized of being, in the first embodiment, provided with one N-type well in which the N-type well PrNW in which the program transistor 2a is formed and the N-type well RNW in which the read transistor 3a is formed are electrically connected to each other as illustrated in FIG. 1. The configuration different from the first embodiment will be focused on and will be described below.

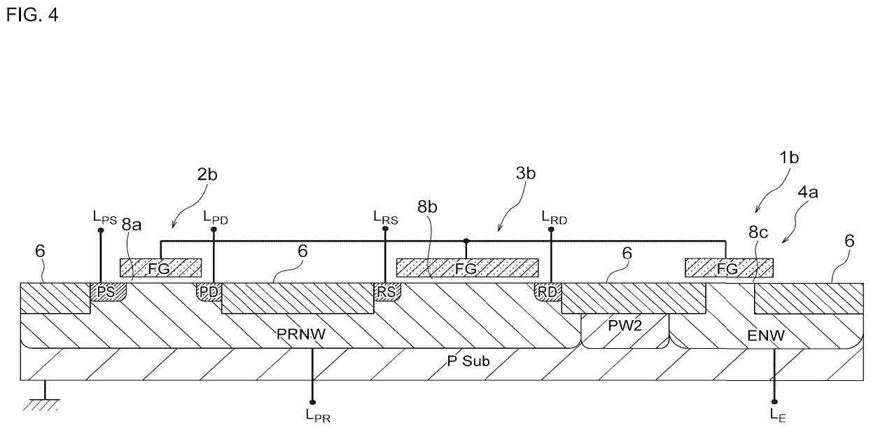

In this case, as illustrated in FIG. 4, in the memory cell 1b, the program transistor 2b and the read transistor 3b are formed in one N-type well PRNW provided in the substrate PSub. A well voltage line LPR is connected to the N-type well PRNW in which the program transistor 2b and the read transistor 3b are formed, and a predetermined voltage is applied to the N-type well PRNW via the well voltage line LPR.

### (2-2) Data Write Operation, Data Erase Operation, and Data Read Operation

The following Table 2 shows specific examples (voltage examples) of combinations of voltages in the data write operation, the data erase operation, and the data read operation in the memory cell 1b. A unit of the voltage value shown in Table 2 is “V”.

TABLE 2

| | Operations | PS | PD | RS | RD | PRNW | ENW | Psub |
|---|---|---|---|---|---|---|---|---|
| Second | Write | 12 | 0 | open | open | 12 | open | 0 |
| Embodiment | Erase | open | open | open | open | 0 | 40 | 0 |
| | Read | open | open | 5 | 0 | 5 | open | 0 |

Table 2 is different in that a column for the N-type well PrNW and a column for the N-type well RNW in Table 1 shown for the memory cell 1a according to the first embodiment are not provided and a column for the N-type well PRNW is provided. The column for the N-type well PRNW in Table 2 specifies the same voltage value as that in the column for the N-type well PrNW in Table 1. In the memory cell 1b, by applying voltages as shown in Table 2, the data write operation, the data erase operation, and the data read operation can be performed, similar to the memory cell 1b according to the first embodiment. The data write operation, the data erase operation, and the data read operation in the second embodiment are the same as the above “(1-4) Data Write Operation”, “(1-5) Data Erase Operation”, and “(1-6) Data Read Operation” except for the operation of applying different well voltages Vprw and Vrw to the N-type well PrNW and the N-type well RNW, and thus the description thereof will be omitted here.

### (2-3) Operations and Effects

The memory cell 1b according to the present embodiment has a configuration in which the program transistor 2b is constituted by a PMOS transistor, and the electrons can be injected into the floating gate FG by the hot electron injection using the CHE, and thus even when the film thickness of the gate insulating film 8a is increased, the charge can be reliably injected into the floating gate FG.

In the memory cell 1b according to the second embodiment, the program transistor 2b and the read transistor 3b are formed in one N-type well PRNW, and thus it is not necessary to form the P-type well PW1 provided in the first embodiment in the substrate PSub, which simplifies the structure and reduces the area of the memory cell 1b.

### (2-4) Other Embodiments of Second Embodiment

In the second embodiment, the memory cell 1b is described as being used in the nonvolatile semiconductor memory device that is a multi-time programmable memory, but the present invention is not limited thereto and may also be, for example, a memory cell used in the nonvolatile semiconductor memory device that is a one-time programmable memory. In the memory cell of the one-time programmable memory, the erase capacitor 4a is not required, and thus the memory cell includes the program transistor 2b and the read transistor 3b.

In the memory cell 1b that does not include the erase capacitor 4a, the data write operation and the data read operation can also be performed in the same manner as the above “(1-4) Data Write Operation” and “(1-6) Data Read Operation” in the first embodiment. In addition, a specific example (voltage example) of the combination of voltages in the data write operation and the data read operation at this time has the same voltage value as the voltage value shown in Table 2.

### (3) Third Embodiment

### (3-1) Configuration of Memory Cell According to Third Embodiment

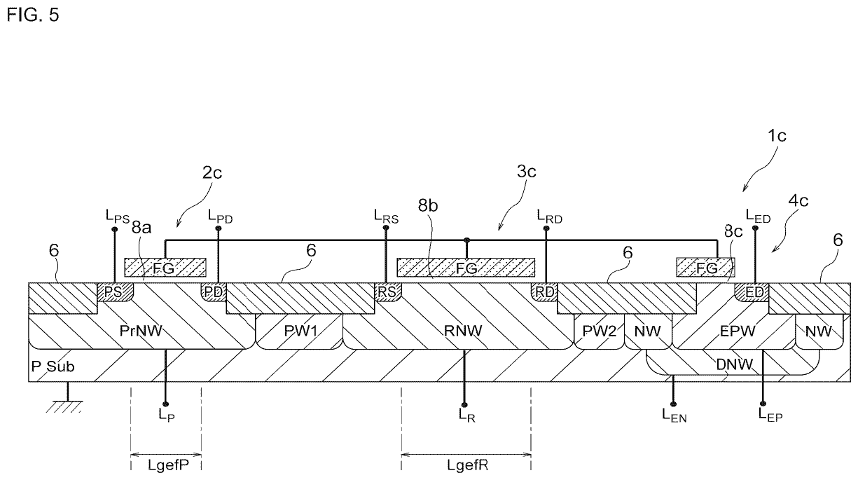

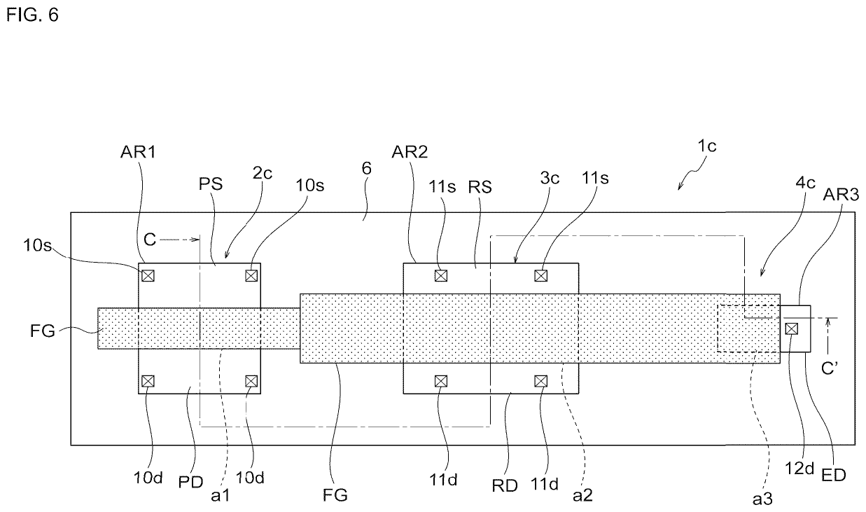

FIG. 5 is a schematic diagram illustrating a side cross-sectional configuration of a memory cell 1c according to a third embodiment. The memory cell 1c according to the third embodiment is used in a nonvolatile semiconductor memory device that is a multi-time programmable memory. FIG. 6 is a schematic diagram illustrating a planar layout example of the memory cell 1c illustrated in FIG. 5. FIG. 5 is a schematic diagram illustrating the side cross-sectional configuration of the memory cell 1c in a part C-C′ of FIG. 6.

In the memory cell 1c, a program transistor 2c, a read transistor 3c, and an erase capacitor 4c are provided on the P-type substrate PSub. The memory cell 1c according to the third embodiment is different from the memory cell 1a according to the first embodiment in the configuration of the erase capacitor 4c. Here, the description of the program transistor 2c and the read transistor 3c having the same configuration as that of the memory cell 1a of the first embodiment will be omitted since they are duplicated, and the configuration of the erase capacitor 4c different from that of the first embodiment will be focused on and will be described below.

The erase capacitor 4c is an NMOS capacitor with a diffusion layer, and is formed d in the P-type well EPW electrically separated from the substrate PSub. The P-type well EPW is electrically separated from the substrate PSub by being surrounded by a deep N-type well DNW and the N-type well NW in a triple well structure. An N-type diffusion layer ED is formed on a surface of the P-type well EPW. The P-type well EPW adjacent to the N-type diffusion layer ED is provided with the gate insulating film 8c made of silicon oxide or the like. The gate insulating film 8c is provided with the floating gate FG electrically connected to the floating gates FG of the program transistor 2c and the read transistor 3c.

A diffusion layer voltage line LED is connected to the N-type diffusion layer ED of the erase capacitor 4c, and a predetermined voltage is applied to the N-type diffusion layer ED via the diffusion layer voltage line LED. A well voltage line LEP is connected to the P-type well EPW in which the erase capacitor 4c is formed, and a predetermined voltage is applied to the P-type well EPW via the well voltage line LEP. A well voltage line LEN different from the well voltage line LEP is connected to the deep N-type well DNW surrounding the P-type well EPW, and a predetermined voltage is applied to the deep N-type well DNW via the other well voltage line LEN.

The film thickness of the gate insulating film 8c of the erase capacitor 4c (distance from the surface of the P-type well EPW to the lower surface of the floating gate FG) is preferably 16 [nm] or more, more preferably 20 [nm] or more, and most preferably 30 [nm] or more. A preferred range of the gate insulating film 8c of the erase capacitor 4c will be described in “(3-3) Data Erase Operation Using BBHH Injection” to be described later.

The substrate PSub is formed with the P-type well PW2 and the N-type well NW between the N-type well RNW in which the read transistor 3c is formed and the P-type well EPW in which the erase capacitor 4c is formed. The P-type well EPW in which the erase capacitor 4c is formed is surrounded by the N-type well NW and the deep N-type well DNW formed below the P-type well EPW, and is electrically separated from the substrate PSub. The N-type well RNW in which the read transistor 3c is formed and the N-type well NW surrounding the P-type well EPW in which the erase capacitor 4c is formed are electrically separated from each other by the P-type well PW2.

The element isolation layer 6 is formed between the active region AR2 on the surface of the N-type well RNW in which the read transistor 3c is formed and the active region AR3 in the surface of the P-type well EPW of the erase capacitor 4c. The active region AR2 of the read transistor 3c and the active region AR3 of the erase capacitor 4c are electrically separated from each other by the element isolation layer 6.

As illustrated in FIG. 6, in the memory cell 1c, one floating gate FG is shared by the program transistor 2c, the read transistor 3c, and the erase capacitor 4c. In the memory cell 1c according to the present embodiment, the program transistor 2c, the read transistor 3c, and the erase capacitor 4c are linearly disposed. The floating gate FG extends so as to intersect the active region AR1 of the program transistor 2c and the active region AR2 of the read transistor 3c, and overlaps a part of the active region AR3 of the erase capacitor 4c.

The floating gate FG disposed in the active region AR3 of the erase capacitor 4c is formed in a rectangular shape in a plan view, and is formed continuously from the floating gates FG of the program transistor 2c and the read transistor 3c. In the present embodiment, the floating gate FG disposed in the active region AR2 of the read transistor 3c extends linearly to a region in which the erase capacitor 4c is formed while maintaining the length of the floating gate FG in the short side direction. In a plan view, the N-type diffusion layer ED is disposed adjacent to the floating gate FG in a direction in which the floating gate FG of the erase capacitor 4c extends. The N-type diffusion layer ED is provided with a columnar contact 12d connected to the diffusion layer voltage line LED.

Here, in FIG. 6, an area at which the floating gate FG disposed in the erase capacitor 4c and the active region AR3 of the erase capacitor 4c face each other is illustrated as a3. In the third embodiment, the area a3 at which the floating gate FG and the active region AR3 of the erase capacitor 4c face each other is preferably 20[%] or less of the total area (area a1+area a2+area a3) of the area a1 at which the floating gate FG and the active region AR1 of the program transistor 2c face each other, the area a2 at which the floating gate FG and the active region AR2 of the read transistor 3c face each other, and the area a3 at which the floating gate FG and the active region AR3 of the erase capacitor 4c face each other, and more preferably 10[%] or less of the total area. By setting the area a3 to 20[%] or less of the total area (area a1+area a2+area a3), a coupling ratio of the erase capacitor 4c can be reduced, and the potential of the floating gate FG can be prevented from being affected during the data write operation or the data erase operation. By setting the area a3 to 10[%] or less of the total area (area a1+area a2+area a3), the coupling ratio of the erase capacitor 4c can be reduced, and the potential of the floating gate FG can be further prevented from being affected during the data write operation or the data erase operation.

The memory cell 1c can also be manufactured by performing a film forming process that is a general manufacturing process of a PMOS transistor, a photolithography process, an etching process, an impurity injection process, and the like, and thus the manufacturing method thereof will be omitted here. The description of the “principle of the data write operation in the memory cell” and the “configuration in which the read transistor is provided separately from the program transistor” in the third embodiment is also the same as that of the first embodiment, and thus the description thereof will be omitted here.

### (3-2) Data Write Operation

Next, the following Table 3 shows a specific example (voltage example) of a combination of voltages during the data write operation using the CHE injection in the memory cell 1c in a column of “Write”. A unit of the voltage value shown in Table 3 is “V”.

TABLE 3

| | Operations | PS | PD | RS | RD | ED | PrNW | RNW | EPW | DNW | PSub |
|---|---|---|---|---|---|---|---|---|---|---|---|
| Third | Write | 12 | 0 | open | open | open | 12 | 16 | open | open | 0 |
| Embodiment | Erase | open | open | open | open | 14 | 0 | 0 | 7 | 8 | 0 |
| | Read | open | open | 5 | 0 | open | 5 | 5 | open | open | 0 |

The voltages applied to respective portions of the program transistor 2c and the read transistor 3c during the data write operation are the same as those of the first embodiment. In the erase capacitor 4c during the data write operation, for example, the N-type diffusion layer ED, the P-type well EPW, and the deep N-type well DNW are opened. Here, the larger the area of the active region facing the floating gate FG is, the larger the effect that the well voltage has on the potential of the floating gate FG by the capacitive coupling. In the erase capacitor 4c, the area a3 at which the floating gate FG and the active region AR3 face each other is 20[%] or less of the total area (area a1+area a2+area a3), and thus the influence of the well voltage Vew of the P-type well EPW on the potential of the floating gate FG can be reduced by the capacitive coupling.

### (3-3) Data Erase Operation Using BBHH Injection

Next, the data erase operation in the memory cell 1c will be described. In the memory cell 1c according to the third embodiment, unlike the first embodiment, the data is erased by injecting the hot holes into the floating gate FG using Band to Band Tunneling induced Hot Hole injection (BBHH).

A BBHH phenomenon is known in which, when a positive high voltage is applied to the drain and a negative high voltage is applied to the gate in the NMOS transistor, the holes are accelerated from the drain toward the well, and are injected into the gate beyond the barrier of the gate insulating film by the energy (see A New Observation of Band-to-Band Tunneling Induced Hot-Carrier Stress Using Charge-Pumping Technique, IEEE Electron Device Letters vol. 21 No. 3 pp 123 (2000)). By using the injection of holes (BBHH injection) according to the BBHH phenomenon, the holes can be injected into the floating gate FG faster than by using the FN tunneling. In addition, by using the BBHH injection, the area a3 at which the floating gate FG and the active region AR3 of the erase capacitor 4c face each other can be reduced. As in the case of the SHH injection of the first embodiment, the holes can be injected into the floating gate FG without applying a high voltage of 40 [V] or more to the well of the erase capacitor 4c.

The above Table 3 shows a specific example (voltage example) of a combination of voltages during the data erase operation using the BBHH injection in a column of “Erase”. In this case, similar to the first embodiment, in the program transistor 2a, the source PS and the drain PD are opened, and the N-type well PrNW is set to 0 [V]. In the read transistor 3a, the source RS and the drain RD are opened, and the N-type well RNW is set to 0 [V]. In addition, the substrate PSub is set to 0 [V].

In the erase capacitor 4c, for example, a diffusion layer voltage V_{ED} of 14 [V] is applied to the N-type diffusion layer ED, and a well voltage Vew of 7 [V] is applied to the P-type well EPW. A well voltage Venw that satisfies a condition under which a forward bias is applied to a junction between the deep N-type well DNW and the P-type well EPW may be applied to the deep N-type well DNW, and for example, a well voltage Venw of 8 [V] is applied to the deep N-type well DNW.

As described above, the larger the area of the active region facing the floating gate FG is, the larger the effect that the well voltage has on the potential of the floating gate FG by the capacitive coupling. In the memory cell 1c according to the present embodiment, the area a3 at which the floating gate FG and the active region AR3 of the erase capacitor 4c face each other is smaller than the total area (area a1+area a2+area a3) of the area a1 at which the floating gate FG and the active region AR1 of the program transistor 2c face each other, the area a2 at which the floating gate FG and the active region AR2 of the read transistor 3c face each other, and the area a3 of the active region AR3 facing the floating gate FG of the erase capacitor 4c, and a coupling ratio represented by the area a3/(area a1+area a2+area a3) is small (for example, 10% or less). Therefore, in the present embodiment, even when a high voltage well voltage Vew of 7 [V] is applied to the active region AR3 of the erase capacitor 4a having a small area a3 at which the active region AR3 and the floating gate FG face each other, the high voltage is less likely to affect the floating gate FG.

In the memory cell 1c, the coupling ratio of the program transistor 2c (area a1/(area a1+area a2+area a3)) and the coupling ratio of the read transistor 3c (area a2/(area a1+ area a2+area a3)) are large, and thus by respectively setting the well voltage Vprw and the well voltage Vrw to 0 [V] during the data erase operation, the potential of the floating gate FG can be adjusted so as not to float with respect to 0 [V].

Therefore, the diffusion layer voltage V_{ED} of 14 [V] is applied to the N-type diffusion layer ED, the well voltage Vew of 7 [V] is applied to the P-type well EPW, and the potential of the floating gate FG is adjusted so as not to float with respect to 0 [V]. In consideration of the potential of the P-type well EPW, a positive high voltage of 7 [V] is applied to the N-type diffusion layer ED, a negative high voltage of −7 [V] is applied to the floating gate FG, and the holes can be injected into the floating gate FG using the BBHH injection. The BBHH phenomenon is caused by a bias condition in which the erase capacitor 4c is in a magnitude relation of the diffusion layer voltage V_{ED}>the well voltage Vew of the P-type well EPW>the voltage of the floating gate FG.

As in the case in which the SHH injection is used in the first embodiment, when the BBHH injection is used as the data erase method, the high-energy hot holes are injected into the floating gate beyond the energy barrier of the gate insulating film, but this energy may cause defects in the gate insulating film, and the holes may be trapped in these defects.

In the third embodiment, as described above, a minimum film thickness of the gate insulating film capable of ensuring the reliability based on Publicly Known Documents 1 and 2 is about 8 [nm], and thus in order to ensure the reliability even when the holes are trapped, the film thickness from the trap position to the substrate may be about 8 [nm], and the film thickness from the trap position to the floating gate may be about 8 [nm]. As described above, when the data erase method using the BBHH is used, the film thickness of the gate insulating film 8c is preferably 16 [nm] or more.

### (3-4) Data Read Operation

As shown in the above Table 3, the voltages applied to the respective portions of the program transistor 2c and the read transistor 3c during the data read operation in the third embodiment are the same as those in the first embodiment. In the erase capacitor 4c, the N-type diffusion layer ED, the P-type well EPW, and the deep N-type well DNW are opened. Accordingly, as in the first embodiment, in the memory cell 1c, for example, the data can also be read by detecting the current flowing between the source RS and the drain RD of the read transistor 3c.

### (3-5) Operations and Effects

The memory cell 1c according to the third embodiment also has a configuration in which the electrons can be injected into the floating gate FG by the hot electron injection using the CHE, and thus the same effect as that of the first embodiment can be obtained. In addition, in the memory cell 1c according to the third embodiment, the erase capacitor 4a is formed in the P-type well EPW electrically separated from the substrate PSub in the triple well structure. The erase capacitor 4c is an NMOS capacitor with a diffusion layer including the N-type diffusion layer ED provided on the surface of the P-type well EPW, the gate insulating film 8c provided on the P-type well EPW adjacent to the N-type diffusion layer ED, and the floating gate FG provided on the gate insulating film 8c. The floating gate FG of the erase capacitor 4c is electrically connected to the floating gate FG of the program transistor 2c and the floating gate FG of the read transistor 3c.

In this way, the memory cell 1c according to the third embodiment has a configuration in which the erase capacitor 4c is constituted by the NMOS capacitor with a diffusion layer and the holes can be injected into the floating gate FG by the hot hole injection using the BBHH, and thus the holes can be injected into the floating gate FG faster than when the FN tunneling is used, and the erase time can be shortened. In addition, when the data is erased using the BBHH, even when the film thickness of the gate insulating film 8c of the erase capacitor 4c is increased, the holes can be injected without increasing the well voltage Vew.

When the erase capacitor 4c is constituted by the NMOS capacitor with a diffusion layer and the data is erased using the BBHH injection, the holes can be injected into the floating gate FG without applying a high voltage of 40 [V] or more to the well, and the erasing can be performed at a low voltage, as compared with that when the erase capacitor is constituted by the PMOS capacitor and the data is erased using the SHH injection. The area a3 at which the floating gate FG and the active region AR3 of the erase capacitor 4c face each other can be reduced, and the coupling ratio of the erase capacitor 4c can be reduced. The potential of the floating gate FG is adjusted so as not to float with respect to 0 [V] by reducing the coupling ratio of the erase capacitor 4c, and the BBHH phenomenon is caused by the bias condition of the magnitude relation of the diffusion layer voltage V_{ED}>the well voltage Vew of the P-type well EPW>the voltage VEG of the floating gate FG, and the holes can be efficiently injected into the floating gate FG.

### (4) Other

The memory cells 1a to 1c according to the first to third embodiments may be used in the nonvolatile semiconductor memory device having circuits that operate at a plurality of different power supply voltages. When the nonvolatile semiconductor memory device has a circuit in which a film thickness of a gate insulating film that operates at a low power supply voltage is less than 16 [nm] and a circuit in which a film thickness of a gate insulating film that operates at a high power supply voltage is 16 [nm] or more, the memory cells 1a to 1c are used in the circuit in which the film thickness of the gate insulating film is 16 [nm] or more.

### REFERENCE SIGN LIST

1a, 1b, 1c memory cell
2a, 2b, 2c program transistor
3a, 3b, 3c read transistor
4a, 4c erase capacitor
8a, 8b, 8c gate insulating film
ED N-type diffusion layer
EPW P-type well
DNW deep N-type well
FG floating gate
PrNW, RNW, ENW, PRNW N-type well
PS, RS source
PD, RD drain

1. A memory cell of a nonvolatile semiconductor memory device, the memory cell comprising:
a program transistor; and
a read transistor, wherein
the program transistor is formed in an N-type well, and includes a drain which is a P-type diffusion layer formed in a surface of the N-type well, a source which is a P-type diffusion layer formed in the surface of the N-type well and separated from the drain, a gate insulating film provided on the N-type well between the drain and the source, and a floating gate provided on the gate insulating film,
the read transistor is formed in an N-type well, and includes a drain which is a P-type diffusion layer formed in a surface of the N-type well, a source which is a P-type diffusion layer formed in the surface of the N-type well and separated from the drain, a gate insulating film provided on the N-type well between the drain and the source, and a floating gate provided on the gate insulating film, and
the floating gate of the program transistor and the floating gate of the read transistor are electrically connected to each other.

2. The memory cell according to claim 1, wherein
the gate insulating films of the program transistor and the gate insulating film of the read transistor each have a film thickness of 16 nm or more.

3. The memory cell according to claim 1, wherein
an effective gate length of the floating gate of the program transistor is smaller than an effective gate length of the floating gate of the read transistor.

4. The memory cell according to claim 1, wherein
a threshold voltage of the program transistor is a voltage on a positive voltage side of a threshold voltage of the read transistor.

5. The memory cell according to claim 1, wherein
the N-type well in which the program transistor is formed and the N-type well in which the read transistor is formed are electrically connected to each other.

6. The memory cell according to claim 1, wherein
the N-type well in which the program transistor is formed and the N-type well in which the read transistor is formed are electrically separated from each other.

7. The memory cell according to claim 1, wherein
an area of an active region of the read transistor facing the floating gate of the read transistor is larger than an area of an active region of the program transistor facing the floating gate of the program transistor.

8. The memory cell according to claim 1, further comprising:
an erase capacitor, wherein
the erase capacitor is formed in an N-type well electrically separated from the N-type well in which the program transistor is formed and the N-type well in which the read transistor is formed, and includes a gate insulating film provided on the N-type well and a floating gate provided on the gate insulating film, and
the floating gate of the erase capacitor is electrically connected to the floating gate of the program transistor and the floating gate of the read transistor.

9. The memory cell according to claim 8, wherein
an area of an active region of the erase capacitor facing the floating gate of the erase capacitor is 10[%] or less of a total area of the area of the active region of the program transistor facing the floating gate of the program transistor, the area of the active region of the read transistor facing the floating gate of the read transistor, and the area of the active region of the erase capacitor facing the floating gate of the erase capacitor.

10. The memory cell according to claim 8, wherein
the active region of the erase capacitor is covered with the floating gate.

11. The memory cell according to claim 6, further comprising:
an erase capacitor, wherein
the erase capacitor is formed in a P-type well, and includes an N-type diffusion layer formed in a surface of the P-type well, a gate insulating film provided in the P-type well adjacent to the N-type diffusion layer, and a floating gate provided on the gate insulating film, and
the floating gate of the erase capacitor is electrically connected to the floating gate of the program transistor and the floating gate of the read transistor.

12. The memory cell according to claim 11, wherein
the gate insulating film of the program transistor, the gate insulating film of the read transistor, and the gate insulating film of the erase capacitor each have a film thickness of 16 nm or more.

13. The memory cell according to claim 11, wherein
an area of an active region of the erase capacitor facing the floating gate of the erase capacitor is 20[%] or less of a total area of an area of an active region of the program transistor facing the floating gate of the program transistor, an area of an active region of the read transistor facing the floating gate of the read transistor, and the area of the active region of the erase capacitor facing the floating gate of the erase capacitor.

14. The memory cell according to claim 11, wherein
the erase capacitor has a voltage V_{ED} applied to the N-type diffusion layer, a well voltage Vew applied to the P-type well, and a voltage V_{FG} of the floating gate satisfying a bias condition of V_{ED}>Vew >V_{FG} during an erase operation.

15. The memory cell according to claim 1, wherein
the nonvolatile semiconductor memory device is a multi-time programmable memory.

16. The memory cell according to claim 1, wherein
the nonvolatile semiconductor memory device is a one-time programmable memory.
